(19) United States
(12) Patent Application Publication
(10) Pub. No.: US 2017/0338114 A1
(43) Pub. Date: Nov. 23, 2017

(54) PATTERN FORMING METHOD, GAS CLUSTER ION BEAM IRRADIATING DEVICE AND PATTERN FORMING APPARATUS

(71) Applicant: Tokyo Electron Limited, Tokyo (JP)

(72) Inventors: Ji Hyun Choi, Hwaseong-si (KR); Young Don Chang, Hwaseong-si (KR)

(21) Appl. No.: 15/534,080

(22) PCT Filed: Nov. 27, 2015
(86) PCT No.: PCT/JP2015/083436

§ 371 Date: Jun. 8, 2017

(30) Foreign Application Priority Data
Dec. 9, 2014 (JP) 2014-249364

(51) Int. Cl. H01L 21/033; H01L 21/02; H01J 37/305; H01L 21/66; H01L 21/311

(52) U.S. Cl. CPC H01L 21/0337; H01L 22/12; H01L 21/31116; H01L 21/31111; H01J 37/3053; H01L 21/0228; H01L 21/0335; H01J 2237/0812; H01J 2237/202

(57) ABSTRACT

A mask pattern is formed on a substrate. A first spacer film is formed on the mask pattern. The first spacer film is etched by irradiating the substrate with a gas cluster ion beam (GCIB). A first spacer pattern is formed on the substrate by removing the mask pattern. A second spacer film is formed on the first spacer pattern. The second spacer film is etched. A second spacer pattern is formed on the substrate by removing the first spacer pattern. The substrate is etched using the second spacer pattern as a mask.

### TECHNICAL FIELD

The various embodiments described herein pertain generally to a pattern forming method, a gas cluster ion beam irradiating device for use in the pattern forming method, and a pattern forming apparatus configured to perform the pattern forming method.

### BACKGROUND ART

As a semiconductor device is highly integrated, a line width of a pattern included in the semiconductor device is getting finer, and a line width of about 10 nm band is required. To form such a fine pattern, SADPT (Self Aligned Double Patterning Technology) or the like is developed. The SADPT is a process of: forming a mask pattern having a narrow line width by performing double patterning; and then forming a fine pattern by using this mask pattern. Further, to form a finer pattern, there has been developed SAQPT (Self Aligned Quadruple Patterning Technology) as a quadruple patterning method of performing double patterning such as SADPT twice consecutively.

In performing such a quadruple patterning method, reactive ion etching (RIE) is widely employed to etch a spacer film formed on a hard mask pattern. That is, in a conventional method, a second hard mask and a first hard mask are formed on a substrate in sequence, and after etching by the RIE method is performed, the second hard mask is etched by using a pattern of a first spacer film, which is obtained in a first double patterning process, as a mask. Then, during a second double patterning process, a second spacer film is formed on a pattern of the second hard. For example, Patent Document 1 discloses etching by RIE.

Patent Document 1: Japanese Patent Laid-open Publication No. 2010-272731

### DISCLOSURE OF THE INVENTION

### Problems to be Solved by the Invention

In the conventional quadruple patterning method, however, since the processes of forming and removing the second hard mask are needed, efficiency is deteriorated and cost is increased.

Furthermore, when performing etching by using the RIE, verticality of ions is low as the ions are incident on the substrate at various angles. Therefore, it is difficult to uniformly etch the entire surface of the substrate to which the ions are irradiated. As a result, a shape of a spacer film formed by the RIE etching becomes non-uniform. For example, since the spacer film has a tapered shape, it may not be easy to form the second spacer film directly on the pattern of the first spacer film which is formed by the first double patterning process.

In view of the foregoing problems, exemplary embodiments provide a pattern forming method capable of improving efficiency of a multiple patterning process while reducing process cost, and also provide a gas cluster ion beam irradiating device and a pattern forming apparatus.

### Means for Solving the Problems

In an exemplary embodiment, a pattern forming method of forming a pattern on a substrate is provided. The method comprises: forming a mask pattern on the substrate; forming a first spacer film on the mask pattern; etching the first spacer film by irradiating a gas cluster ion beam (GCIB) to the substrate; forming a first spacer pattern on the substrate by removing the mask pattern; forming a second spacer film on the first spacer pattern; etching the second spacer film; forming a second spacer pattern on the substrate by removing the first spacer pattern; and etching the substrate by using the second spacer pattern as a mask.

In another exemplary embodiment, a gas cluster ion beam irradiating device is provided. The gas cluster ion beam irradiating device comprises: a gas cluster ion beam generating unit configured to generate a gas cluster ion beam; a substrate driving unit configured to support the substrate having an irradiation surface on which a mask pattern and a first spacer film are formed in sequence, and to drive the substrate such that the gas cluster ion beam is irradiated onto the substrate; and a control unit configured to control the substrate driving unit. The control unit performs a control such that the first spacer film is etched by irradiating the gas cluster ion beam to the irradiation surface of the substrate.

In still another exemplary embodiment, a pattern forming apparatus configured to form a pattern on a substrate is provided. The pattern forming apparatus comprises: a mask pattern forming module configured to form a mask pattern on the substrate; a first spacer film forming module configured to form a first spacer film on the mask pattern; a gas cluster ion beam irradiating device configured to etch the first spacer film by irradiating a gas cluster ion beam to the substrate; a first spacer pattern forming module configured to form a first spacer pattern on the substrate by removing the mask pattern; a second spacer film forming module configured to form a second spacer film on the first spacer pattern; a second spacer film etching module configured to etch the second spacer film; a second spacer pattern forming module configured to form a second spacer pattern on the substrate by removing the first spacer pattern; and a substrate etching module configured to etch the substrate by using the second spacer pattern as a mask.

### Effect of the Invention

As stated above, the pattern forming method, the gas cluster ion beam irradiating device and the pattern forming method according to the exemplary embodiments have effects of improving efficiency of a multiple patterning process and reducing process cost.

### BRIEF DESCRIPTION OF THE DRAWINGS

FIG. 1A to FIG. 1I are cross sectional views of a substrate illustrating individual processes of quadruple patterning according to a first exemplary embodiment.

FIG. 2 is a cross sectional view of a substrate for describing a profile of a spacer film etched by using a gas cluster ion beam according to the first exemplary embodiment.

FIG. 3A to FIG. 3H are cross sectional views of a substrate illustrating individual processes of quadruple patterning according to a second exemplary embodiment.

FIG. 4 is a schematic side view illustrating a configuration of a gas cluster ion beam irradiating device according to an exemplary embodiment.

FIG. 5 is a schematic front view of a substrate driving unit included in the gas cluster ion beam irradiating device according to the exemplary embodiment.

FIG. 6A is a diagram for describing an example method of irradiating a gas cluster ion beam to a substrate surface according to an exemplary embodiment.

FIG. 6B is a diagram for describing another example method of irradiating a gas cluster ion beam to a substrate surface according to the exemplary embodiment.

FIG. 7 is a schematic plane view of a pattern forming apparatus according to an exemplary embodiment.

FIG. 8A to FIG. 8J are cross sectional views of a substrate illustrating individual processes of conventional quadruple patterning.

FIG. 9 is a cross sectional view for describing a profile of a spacer film etched by reactive ion etching (RIE).

### DETAILED DESCRIPTION

In the following, a pattern forming method, a gas cluster ion beam irradiating device and a pattern forming apparatus according to exemplary embodiments will be described in detail, and reference is made to the accompanying drawings, which form a part of the description. Here, it should be noted that the exemplary embodiments are not limiting. Throughout the whole document, same or corresponding parts will be assigned same reference numerals.

(Example of Conventional Quadruple Patterning)

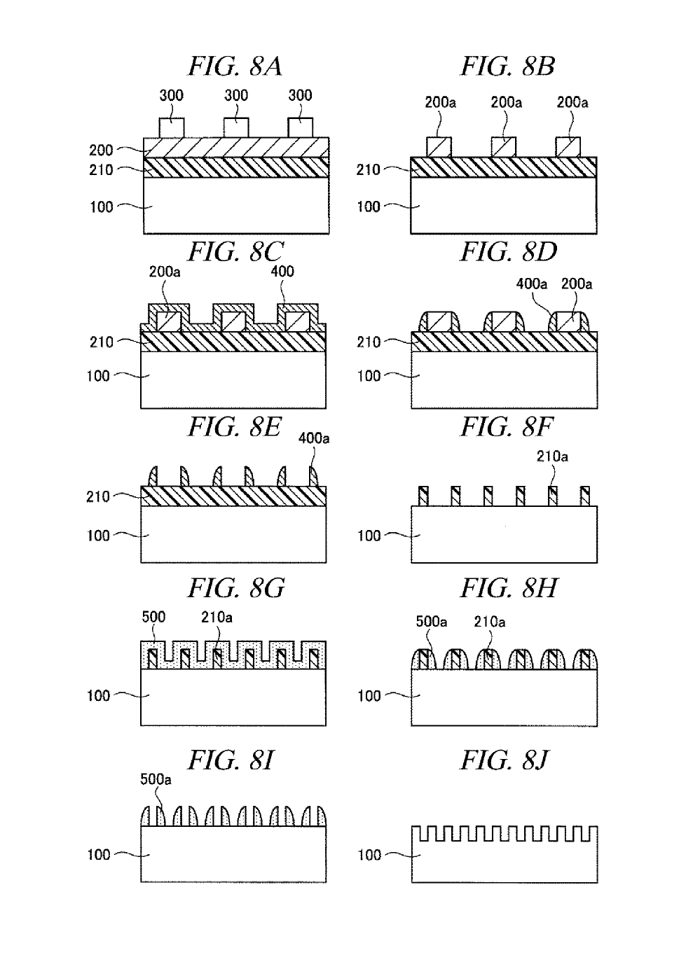

First, an example of quadruple patterning in the conventional art will be explained with reference to FIG. 8A to FIG. 8J. FIG. 8A to FIG. 8J are cross sectional views of a substrate illustrating individual processes of the conventional quadruple patterning method. Though the following exemplary embodiments will be described for an example of quadruple patterning, the exemplary embodiments are not limited thereto and may be applicable to any of multiple patterning processes including a process of forming an additional spacer film on a spacer film.

As depicted in FIG. 8A to FIG. 8J, in the quadruple patterning according to the prior art, a second hard mask layer 210 and a first hard mask layer 200 are formed on a substrate 100 in sequence. Then, photoresist patterns 300 are formed on the first hard mask 200 (FIG. 8A). Thereafter, the first hard mask layer 200 is etched by using the photoresist patterns 300 as an etching mask, so that first hard mask patterns 200a are formed (FIG. 8B).

Thereafter, a first spacer film 400 is formed on the first hard mask patterns 200a (FIG. 8C). Afterwards, a part of the first spacer film 400 is etched by using RIE or the like (FIG. 8D). Then, the first hard mask patterns 200a are removed, so that patterns 400a of the first spacer film 400 are obtained on the second hard mask 210 (FIG. 8E). Next, the second hard mask 210 is etched by using the patterns 400a of the first spacer film 400 as a mask, so that second mask patterns 210a are formed (FIG. 8F).

Subsequently, a second spacer film 500 is formed on the second hard mask patterns 210a (FIG. 8G). Then, a part of the second spacer film 500 is etched by using RIE or the like (FIG. 8H), and patterns 500a of the second spacer film 500 are formed by etching the second hard mask patterns 210a (FIG. 8I). Thereafter, the substrate 100 is etched by using the patterns 500a of the second spacer film 500 as a mask, so that a desired pattern is obtained (FIG. 8J).

(Shape of Spacer Film in Case of Using RIE)

In the prior art shown in FIG. 8A to FIG. 8J, since the first spacer film 400 is etched by using the RIE, the patterns 400a of the first spacer film 400 are formed on sidewalls of the first hard mask pattern 200a in, for example, a tapered shape, as illustrated in FIG. 8D.

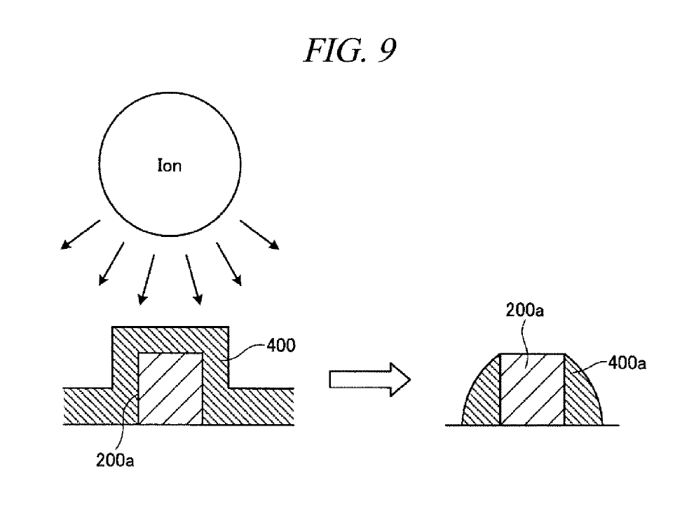

FIG. 9 is a cross sectional view of a substrate for describing a profile of a spacer film etched by RIE. As shown in FIG. 9, in the conventional etching using the RIE, since all ions do not collide with a surface of the substrate from a direction orthogonal to the surface of the substrate but collide with the surface of the substrate at different angles from multiple directions, verticality of the ions is low. Thus, in case of etching the first spacer film 400 by the RIE after forming the first spacer film 400 on the first hard mask patterns 200a conformally, an etching amount of a corner portion of the first spacer film 400 becomes larger than that of the other portion thereof. As a result, the patterns 400a of the spacer film 400 after the etching have tapered shapes.

If the patterns 400a of the first spacer film 400 have the tapered shapes, it is difficult to form the second spacer film 500 directly on the patterns 400a of the first spacer film 400 in a uniform manner. Accordingly, in the conventional art, the second hard mask layer 210 additionally formed under the second spacer film 500 is etched, and the second spacer film 500 is then formed on the second hard mask patterns 210a. According to this process, however, the additional process of forming the second hard mask layer 210 is required, and also, the process of removing the second hard mask patterns 210a by etching is additionally required. Therefore, efficiency of the process is deteriorated, and process cost is increased.

### Example of Quadruple Patterning According to First Exemplary Embodiment

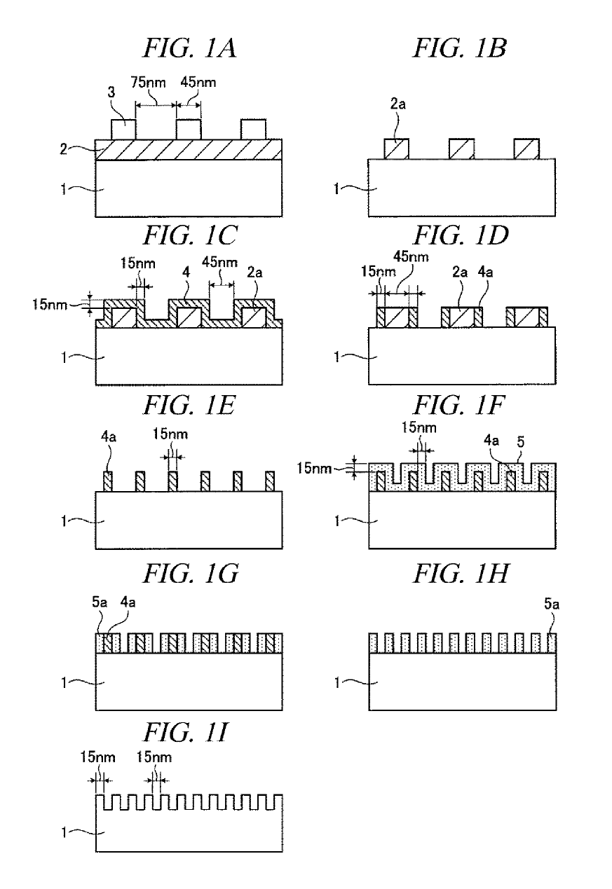

FIG. 1A to FIG. 1I are cross sectional views of a substrate for illustrating individual processes of quadruple patterning according to a first exemplary embodiment. Referring to FIG. 1A to FIG. 1I, the quadruple pattering according to the first exemplary embodiment will be explained in comparison with the quadruple pattering of the prior art shown in FIG. 8A to FIG. 8J.

In the first exemplary embodiment, as illustrated in FIG. 1A, a hard mask layer 2 is formed on a substrate 1 which is made of, for example, silicon, and photoresist patterns 3 are formed on the hard mask layer 2.

By way of example, the hard mask layer 2 may be formed by depositing a silicon oxide through a PE-CVD process. Alternatively, the hard mask layer 2 may be formed by using a silicon-based spin-on hard mask such as a spin-on glass (SOG). As an example, but not limitation, each photoresist pattern 3 may have a width of about 45 nm, and a distance between the photoresist patterns 3 may be about 75 nm. Here, however, it should be noted the aforementioned width of the photoresist patterns 3 and the distance therebetween are nothing more than examples and may not be limited thereto. Further, the individual patterns may be set to have different widths and different distances therebetween.

Furthermore, in the above description, the “width” of the photoresist pattern 3 refers to a length thereof along the surface of the substrate 1 in a certain direction. For example, a length of the substrate in a transversal direction on the plane of FIG. 1A to FIG. 1I may be defined as the “width” of the substrate.

Next, as depicted in FIG. 1B, the hard mask layer 2 is etched by using the photoresist patterns 3 as a mask, so that hard mask patterns 2a are formed.

Further, as shown in FIG. 1C, a first spacer film 4 is formed on the hard mask patterns 2a. At this time, the first spacer film 4 is formed along the hard mask patterns 2a to conform thereto. By way of example, the first spacer film 4 may have a thickness of about 15 nm, and a distance between the first spacer film 4 formed on a hard mask pattern 2a and the first spacer film 4 formed on an adjacent hard mask pattern 2a may be set to about 45 nm.

The formation of the first spacer film 4 may be performed by using atomic layer deposition (ALD). Though the first spacer film 4 may be formed by chemical vapor deposition (CVD), a thickness of the spacer film formed on top surfaces of the mask patterns tends to be larger than a thickness of the spacer film formed on side surfaces of the mask patterns. In such a case, a step coverage of the spacer film is degraded. In contrast, if the first spacer film 4 is formed by using the ALD, the thickness of the spacer film formed on the top surfaces of the mask patterns and the thickness of the spacer film formed on the side surfaces of the mask patterns have values having a ratio of about 1:1, so that it is possible to obtain the spacer film having a high step coverage. The first spacer film 4 may be made of a material having etching selectivity against the hard mask patterns 2a. By way of non-limiting example, the first spacer film 3 may be an oxide film made of an ALD oxide.

As depicted in FIG. 1D, the first spacer film 4 is anisotropically etched by using a gas cluster ion beam (GCIB). Though verticality of the gas cluster ion beam is improved as a diameter of the gas cluster ion beam gets smaller, the diameter of the gas cluster ion beam may be set to an appropriate value in consideration of throughput. For example, the diameter of the gas cluster ion beam may set to be equal to or less than about 1 cm. Characteristics of the etching using the gas cluster ion beam will be discussed later.

The etching by the gas cluster ion beam is performed until the top surfaces of the hard mask patterns 2a are exposed. For example, the etching is performed such that the first spacer film 4 is uniformly etched by a thickness of 15 nm across the entire surface of the substrate. By way of example, irradiation of the gas cluster ion beam to the entire surface of the substrate 1 is achieved by moving the substrate 1 while irradiating the gas cluster ion beam onto the substrate 1. For instance, the substrate 1 is supported from a direction perpendicular to the irradiation surface, and the gas cluster ion beam is irradiated from a direction perpendicular to the irradiation surface while moving the substrate 1 in a direction parallel to the irradiation surface. At this time, by moving the substrate 1 upwards or downwards while moving the substrate 1 to the left and to the right alternately, it is possible to irradiate the gas cluster ion beam to the entire surface of the substrate 1. That is, the substrate 1 needs to be moved in one direction perpendicular to the direction parallel to the irradiation surface while being moved in that one direction and in the opposite direction alternately.

Through this process, as illustrated in FIG. 1D, patterns 4a of the first spacer film 4 having a width of about 15 nm can be formed on side surfaces of the hard mask patterns 2a. The patterns 4a do not have a tapered shape but may have a rectangular shape.

Subsequently, as depicted in FIG. 1E, the hard mask patterns 2a are removed by etching. For example, only the hard mask patterns 2a can be removed by using an etchant which etches only the hard mask patterns 2a without etching the patterns 4a of the first pacer film 4. As a result, only the patterns 4a of the first spacer film 4 having the width of about 15 nm are left on the substrate 1.

Referring to FIG. 1F, the second spacer film 5 is conformally formed on the patterns 4a of the first spacer film 4. The second spacer film 5 may be made of a material which is different from the material of the first spacer film 4 and has etching selectivity against the first spacer film 4. By way of non-limiting example, the second spacer film 5 may be an ALD silicon nitride (SiN) film. By forming the second spacer film 5 by ADL as in the case of the first spacer film 4, the second spacer film can be given a high step coverage. By way of example, but not limitation, the second spacer film 5 may have a thickness of about 15 nm, and a distance between the second spacer film 5 on each pattern 4a and the second spacer film 5 on each adjacent pattern 4a may be approximately 15 nm.

As shown in FIG. 1G, etching of the second spacer film 5 is performed on the entire surface of the substrate 1. The second spacer film 5 may be etched by irradiating a gas cluster ion beam, as in the case of the first spacer film 4. Since, however, an additional spacer film need not be formed on the remaining second spacer film 5 after the etching, it may be more efficient to etch the second spacer film 5 by using RIE featuring a shorter etching time in consideration of throughput of the process.

As depicted in FIG. 1H, the patterns 4a of the first spacer film 4 are removed by being etched selectively, so that only patterns 5a of the second spacer film 5 are formed on the substrate 1. By way of example, the patterns 4a of the first spacer film 4 may be etched by performing a treatment on the entire surface of the substrate with a HF (Hydrogen Fluoride) solution.

Next, as shown in FIG. 1I, the substrate 1 is etched by using the patterns 5a of the second spacer film 5 as a mask. As a result, patterns having a pattern interval of, e.g., about 15 nm can be formed.

### Characteristics of Etching Using Gas Cluster Ion Beam

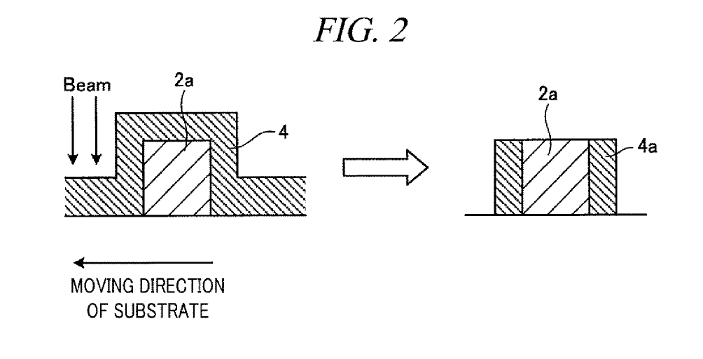

FIG. 2 is a cross sectional view of a substrate for describing a profile of a spacer film etched by using a gas cluster ion beam according to the first exemplary embodiment. Referring to FIG. 2, etching by using the gas cluster ion beam will be explained.

As stated before with reference to FIG. 9, in the etching using the conventional RIE, since incidence directions or incidence angles of ion beams upon the substrate are different, a corner portion of a spacer film is etched in a larger amount.

In contrast, since the gas cluster ion beam has high verticality as stated above, the gas cluster ion beam is irradiated to the substrate from a direction substantially orthogonal to the irradiation surface of the substrate. Furthermore, by scanning the entire irradiation surface of the substrate by moving the substrate, the gas cluster ion beam can be irradiated to the entire surface of the substrate, so that the first spacer film 4 can be etched in a uniform amount across the entire surface of the substrate. As a result, the profile of the patterns 4a of the first spacer film 4 has a substantially rectangular shape, and it is possible to form the second spacer film 5 directly on the patterns 4a of the first spacer film 4.

### Effects of the First Exemplary Embodiment

According to the first exemplary embodiment, the patterns 4a of the first spacer film 4 formed by the etching with the gas cluster ion beam have the rectangular shape, so that the second spacer film 5 can be directly formed on the patterns 4a of the first spacer film 4 conformally. Thus, unlike in the prior art, an additional hard mask need not be formed on the substrate. Hence, since processes regarding forming and etching of an additional hard mask can be omitted, efficiency of the process can be improved, and process cost can be greatly reduced.

As stated above, according to the first exemplary embodiment, when performing the quadruple patterning process, the spacer film formed on the hard mask during the first double patterning process is etched by using the gas cluster ion beam. Therefore, the pattern of the spacer film can be still used in the second double patterning process which is performed after the first patterning process. Therefore, the number of processes can be reduced in the multiple patterning, so that process efficiency can be improved and cost can be cut.

### Example of Quadruple Patterning According to Second Exemplary Embodiment

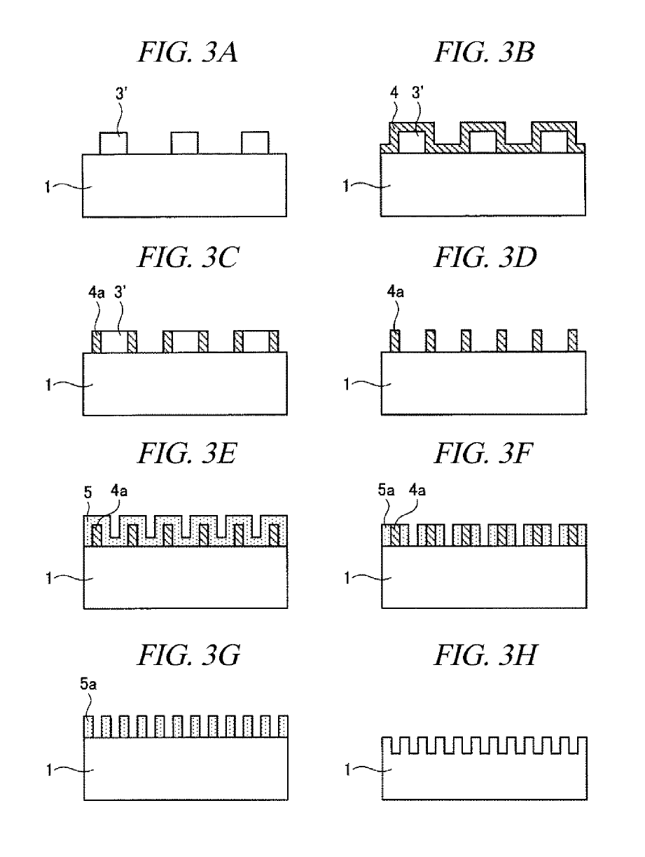

FIG. 3A to FIG. 3H are cross sectional views of a substrate illustrating individual processes of quadruple patterning according to a second exemplary embodiment. Since processes shown in FIG. 3B to FIG. 3G are the same as the processes shown in FIG. 1C to FIG. 1I, respectively, the processes in FIG. 3B to FIG. 3G may be performed in the same manner as the processes shown in FIG. 1C to FIG. 1I. Thus, in the following description, specific explanation of the individual processes of the second exemplary embodiment will be omitted, and only distinctive features from the first exemplary embodiment will be elaborated.

In the second exemplary embodiment, the process shown in FIG. 1A is not performed. That is, in the second exemplary embodiment, a hard mask layer 2 is not formed on a silicon substrate 1, and photoresist patterns 3′ are directly formed (FIG. 3A) and a first spacer film 4 is formed on the photoresist patterns 3′ (FIG. 3B). Then, by anisotropically etching the first spacer film 4 by using a gas cluster ion beam, patterns 4a of the first spacer film are formed (FIG. 3C). Processes shown in FIG. 3D to FIG. 3H are the same as the processes shown in FIG. 1E to FIG. 1I, respectively. Further, processes shown in FIG. 3A to FIG. 3C may be performed in the same manner as the processes shown in FIG. 1B to FIG. 1D, respectively. A thickness and a width of the spacer film and the like may also be set to be the same as those of the first exemplary embodiment.

As stated above, in the second exemplary embodiment, the hard mask layer 2 of FIG. 1A is not formed, and the photoresist patterns 3′ are directly formed on the silicon substrate 1. In this case, since the photoresist patterns 3′ may be damaged in a subsequent etching process, it may be desirable to use the photoresist patterns 3′ after performing a hardening treatment on the photoresist patterns 3′ to prevent a damage by the etching.

### Effects of Second Exemplary Embodiment

As stated above, in the second exemplary embodiment, since the first spacer film 4 is formed on the hardened photoresist patterns 3,′ the processes (shown in FIG. 1A and FIG. 1B) regarding forming and etching of a hard mask layer can be omitted. Therefore, according to the second exemplary embodiment, the number of required processes can be further reduced as compared to the first exemplary embodiment.

### Example of Gas Cluster Ion Beam Irradiating Device According to Exemplary Embodiment)

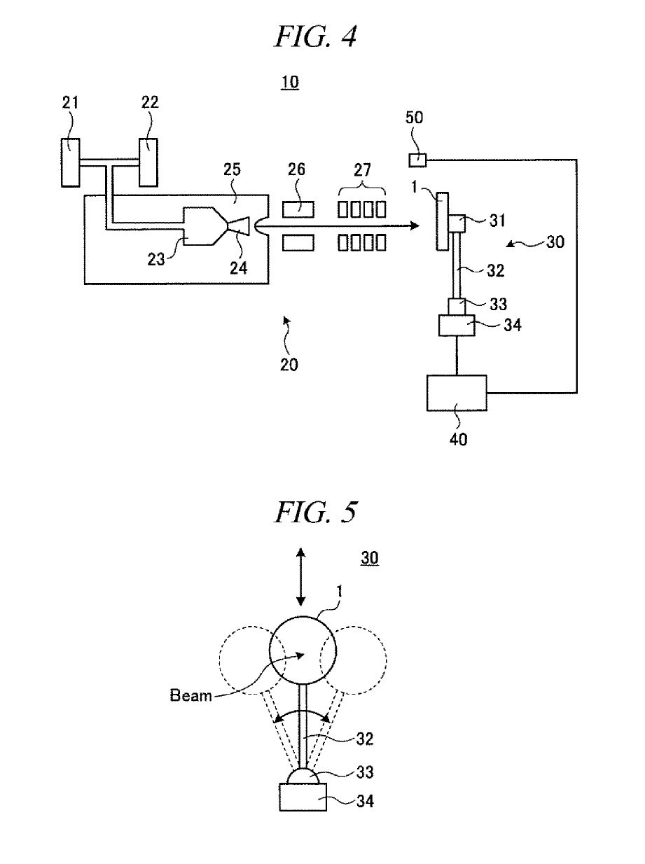

FIG. 4 is a schematic side view illustrating a configuration of a gas cluster ion beam irradiating device according to an exemplary embodiment, and FIG. 5 is a schematic front view of a substrate driving unit within the gas cluster ion beam irradiating device.

As depicted in FIG. 4, the gas cluster ion beam irradiating device 10 includes a gas cluster ion beam generating unit 20; a substrate driving unit 30; and a control unit 40. The gas cluster ion beam generating unit 20 generates a gas cluster ion beam. The substrate driving unit 30 holds and drives the substrate 1 such that the gas cluster ion beam is irradiated onto the substrate 1. The control unit 40 controls the substrate driving unit 30.

The gas cluster ion beam generating unit 20 is equipped with one or more gas supply sources, for example, a first gas supply source 21 and a second gas supply source 20. The first gas supply source 21 and the second gas supply source 22 may be used individually or in combination to generate an ionized cluster.

A high-pressure condensable gas containing either or both of a first gas composition supplied from the first gas supply source 21 and a second gas composition supplied from the second gas supply source 22 is introduced into a stationary chamber 23 and flows out into a vacuum having a pressure substantially lower than an internal pressure of the stationary chamber 23 through a nozzle 24. As the high-pressure condensable gas is expanded after flowing into a low-pressure region of a source chamber 25 from the stationary chamber 23, a gas velocity is accelerated to an ultrasonic wave velocity, and a gas cluster beam comes out of the nozzle 24.

After the gas cluster beam is formed within the source chamber 25, a gas cluster forming the gas cluster beam is ionized to produce a gas cluster ion beam (GCIB) in an ionization device 26. A high-voltage electrode 27 withdraws cluster ions from the ionization device 26 and accelerates the cluster ions to a preset energy level. A kinetic energy of the cluster ions of the gas cluster ion beam produced as stated above may be in the range from about 1000 electronic volt (1 keV) to several tens of keV.

The substrate 1 to which the gas cluster ion beam is irradiated is supported by the substrate driving unit 30. The gas cluster ion beam is irradiated to an entire region of a surface (hereinafter, referred to as “irradiation surface”) of the substrate 1 on the side where the gas cluster beam is irradiated.

The substrate driving unit 30 includes a holding unit 31; a supporting rod 32, a rotation shaft 33 and an elevating device 34. The holding unit 31 holds the substrate 1 from a vertical direction (a direction substantially parallel to the irradiation surface in FIG. 4). The supporting rod 32 is connected to the holding unit 31 and is extended in the vertical direction. The rotation shaft 33 is provided at a lower end of the supporting rod 32. The elevating device 34 is a longitudinal direction moving device which supports the rotation shaft 33 and is capable of moving the rotation shaft 33 up and down.

The supporting rod 32 may be extended from the rotation shaft 33 in a radial direction of a circle centered on the rotation shaft 33 and configured to reciprocate within a preset angular range with respect to the rotation shaft 33. Accordingly, by the movement of the supporting rod 32, the substrate 1 is reciprocally moved forming a circular arc like a pendulum, and the rotation shaft 33 may serve as a transversal direction moving device of the substrate driving unit 30.

Here, the “longitudinal direction” means an up-down direction on the plane of FIG. 4, and the “transversal direction” refers to a direction toward an inner side from a front side of the plane of FIG. 4.

The control unit 40 is connected to the substrate driving unit 30 and controls the substrate driving unit 30. To elaborate, the control unit 40 controls the substrate driving unit 30 to move the substrate 1 supported by the substrate driving unit 30 while the cluster ion beam is irradiated onto the substrate 1 such that the first spacer film 4 formed on the substrate 1 provided with the mask pattern is etched by the gas cluster ion beam across the entire irradiation surface of the substrate. By way of example, the control unit 40 may move the substrate 1 upwards or downwards by controlling the elevating device 34 while moving the substrate 1 to the left and to the right alternately by controlling the rotation shaft 33, thus allowing the gas cluster ion beam to be irradiated to the entire irradiation surface of the substrate 1.

Furthermore, the gas cluster ion beam irradiating device 10 may further include a thickness measuring unit 50 configured to measure a thickness of the first spacer film 4 being etched in correspondence to a position of the first spacer film 4 on the substrate 1. The control unit 40 may control a moving speed of the substrate 1 based on the thickness of the first spacer film 4 measured by the thickness measuring unit 50 and the position of the first spacer film 4 on the substrate 1. Through this operation, even in case that a step coverage is not high when forming the first spacer film 4 on the mask pattern, it is possible to easily form the patterns 4a of the first spacer film 4 to have a desired shape, for example, a rectangular shape.

FIG. 5 is a schematic front view of the substrate driving unit 30 belonging to the gas cluster ion beam irradiating device 10 according to the exemplary embodiment. Referring to FIG. 5, an example of a driving mechanism of the substrate driving unit 30 will be explained in detail. As depicted in FIG. 5, if the supporting rod 32 reciprocates in the direction of the circular arc with respect to the rotation shaft 33, the substrate 1 supported by the holding unit 31 is moved in a left-right direction (in the transversal direction in FIG. 4), so that the irradiation of the gas cluster ion beam to the substrate 1 can be achieved. Further, if the substrate 1 is moved upward or downwards by the elevating device 34, the irradiation of the gas cluster ion beam can be performed in an up-down direction of the substrate. Thus, by moving the substrate 1 upwards or downwards by the elevating device while moving the substrate 1 repeatedly in the left-right direction by the rotation shaft 33, it is possible to irradiate the gas cluster ion beam to the entire surface of the substrate 1.

Further, the exemplary embodiment is not limited to the example shown in FIG. 5. The holding unit 31 configured to support the substrate 1 may include a rotation motor, and the substrate 1 may be moved upwards or downwards by the elevating device 34 while being rotated by the rotation motor. This operation also enables the gas cluster ion beam to be irradiated to the entire surface of the substrate 1.

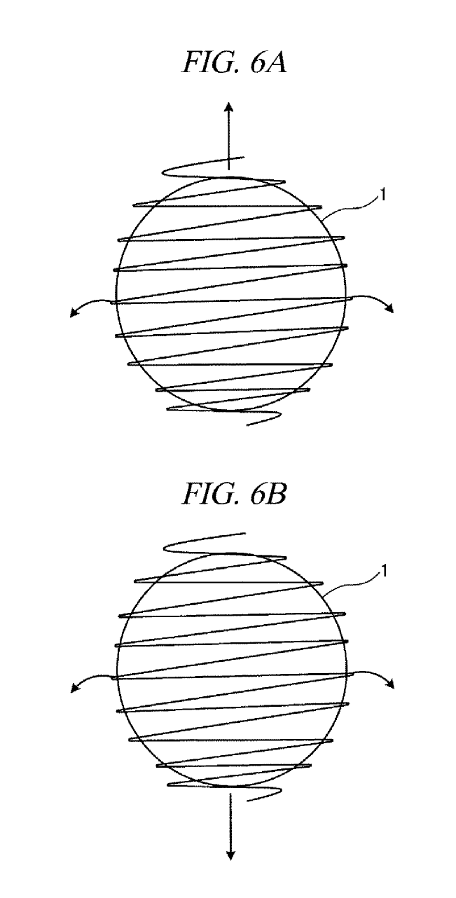

FIG. 6A and FIG. 6B are diagrams for describing an example of a method of irradiating the gas cluster ion beam to the surface of the substrate according to an exemplary embodiment. Referring to FIG. 6A and FIG. 6B, a method of scanning the entire surface of the substrate 1 by the substrate driving unit 30 will be explained in detail.

FIG. 6A illustrates a case where the gas cluster ion beam is irradiated from an upper side of the substrate 1 which is supported by the holding unit 31 such that the irradiation surface substantially coincides with the vertical direction. By moving the substrate 1 upwards while moving the substrate 1 to the left and to the right alternately, the gas cluster ion beam can be uniformly irradiated to the entire irradiation surface of the substrate 1. FIG. 6B illustrates a case where the gas cluster beam is irradiated from a lower side the substrate 1 which is supported by the holding unit 31 such that the irradiation surface substantially coincides with the vertical direction. By moving the substrate 1 downwards while moving the substrate 1 to the left and to the right alternately, the gas cluster ion beam can be uniformly irradiated to the entire irradiation surface of the substrate 1.

### Example of Pattern Forming Apparatus According to Exemplary Embodiment

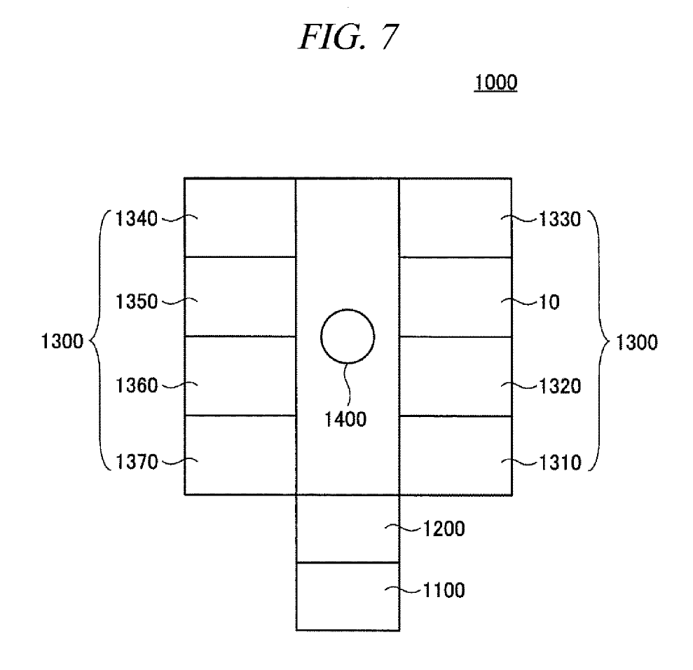

FIG. 7 is a plane view illustrating a pattern forming apparatus according to an exemplary embodiment. According to the exemplary embodiment, the pattern forming apparatus 1000 includes a loading/unloading unit 1100, a load lock chamber 1200 and a multiple number of processing chambers 1300 and a substrate transfer device 1400.

The loading/unloading unit 1100 is configured to load or unload a substrate. The load lock chamber 1200 serves as a buffer room between the loading/unloading unit 1100 and the processing chambers. Each of the processing chambers 1300 is configured as a space in which a process is performed on the substrate. Here, the reference number 1300 denotes the multiple number of processing chambers altogether. The substrate transfer device 1400 is configured to unload a processed substrate 1 from a processing chamber 1300 or transfer a non-processed substrate 1 into the processing chamber 1300.

In each of the multiple number of processing chambers 1300, devices necessary for forming patterns on the substrate 1 are installed in the form of modules. By way of example, each of the processing chambers 1300 arranged on the right side of FIG. 7 is equipped with a mask pattern forming module 1310, a first spacer film forming module 1320, a gas cluster beam irradiating device 10 and a first spacer pattern forming module 1330. Further, each of the processing chambers 1300 arranged on the left side of FIG. 7 is equipped with a second spacer film forming module 1340, a second spacer film etching module 1350, a second spacer pattern forming module 1360 and a substrate etching module 1370.

The mask pattern forming module 1310 is configured to form a mask pattern on the substrate. The first spacer film forming module 1320 is configured to form a first spacer film on the mask pattern. The gas cluster ion beam irradiating device 10 is configured to anisotropically etch the first spacer film by irradiating a gas cluster ion beam to the substrate. Further, the first spacer pattern forming module 1330 is configured to form a first spacer pattern on the substrate by removing the mask pattern. The second spacer film forming module 1340 is configured to a second spacer film on the first spacer pattern. The second spacer film etching module 1350 is configured to anisotropically etch the second spacer film. The second spacer pattern forming module 1360 is configured to form a second spacer pattern on the substrate by removing the first spacer pattern. The substrate etching module 1370 is configured to etch the substrate by using the second spacer pattern as a mask.

With the above-described configuration, individual processes for forming the pattern by quadruple patterning can be performed in the single apparatus. In the present exemplary embodiment, the pattern forming process is performed in the single apparatus in which the devices for performing the individual processes are configured as the individual modules. However, the individual modules may be configured as separate apparatuses, and the individual processes may be performed in the separate apparatuses individually.

### Effect of Exemplary Embodiments

According to the exemplary embodiments, by performing the etching of the first spacer film by irradiating the gas cluster ion beam, processes regarding forming and etching of an additional hard mask can be omitted in a fine pattern forming process by quadruple patterning in which double patterning is performed twice consecutively. Accordingly, the total number of processes can be reduced, so that process efficiency can be improved and process cost can be greatly reduced in the manufacture of a semiconductor device.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the illustrative embodiments. It shall be understood that all modifications and embodiments conceived from the meaning and scope of the claims and their equivalents are included in the scope of the inventive concept.

### EXPLANATION OF REFERENCE NUMERALS

1: Substrate

2: Hard mask layer

2a: Hard mask pattern

3, 3′: Photoresist pattern

4: First spacer film

4a: Pattern of first spacer film

5: Second spacer film

5a: Pattern of second spacer film

10: Gas cluster ion beam irradiating device

20: Gas cluster ion beam generating unit

21: First gas supply source

22: Second gas supply source

23: Stationary chamber

24: Nozzle

25: Source chamber

26: Ionization device

27: High-voltage electrode

30: Substrate driving unit

31: Holding unit

32: Supporting rod

33: Rotation shaft

34: Elevating device

40: Control unit

50: Thickness measuring unit

1000: Pattern forming apparatus

1100: Loading/unloading unit

1200: Load lock chamber

1300: Processing chamber

1400: Substrate transfer device

1. A pattern forming method of forming a pattern on a substrate, the method comprising:
forming a mask pattern on the substrate;
forming a first spacer film on the mask pattern;
etching the first spacer film by irradiating a gas cluster ion beam (GCIB) to the substrate;
forming a first spacer pattern on the substrate by removing the mask pattern;
forming a second spacer film on the first spacer pattern;
etching the second spacer film;
forming a second spacer pattern on the substrate by removing the first spacer pattern; and
etching the substrate by using the second spacer pattern as a mask.

2. The pattern forming method of claim 1,
wherein the step of forming the mask pattern comprises:
forming a single hard mask layer on the substrate and forming a photoresist pattern on the hard mask layer; and
forming the mask pattern by etching the hard mask layer by using the photoresist pattern as a mask.

3. The pattern forming method of claim 1 or 2,
wherein the step of etching the first spacer film comprises:
moving the substrate while irradiating the gas cluster ion beam onto the substrate.

4. The pattern forming method of claim 3,
wherein the substrate is held such that an irradiation surface of the substrate to which the gas cluster ion beam is irradiated is extended in a vertical direction,
the gas cluster ion beam is irradiated in a horizontal direction substantially perpendicular to the irradiation surface of the substrate; and
the gas cluster ion beam is irradiated to the entire irradiation surface of the substrate by moving the substrate upwards or downwards while moving the substrate substantially horizontally in one direction and the opposite direction alternately.

5. The pattern forming method of claim 3,
wherein the step of etching the first spacer film comprises:
measuring a thickness of the first spacer film at each position on the substrate; and
controlling a moving speed of the substrate based on the position on the substrate and the measured thickness.

6. The pattern forming method of claim 1,
wherein the first spacer film and the second spacer film are made of different materials from each other.

7. The pattern forming method of claim 1,
wherein the step of forming the first spacer film is performed by using ALD (Atomic Layer Deposition).

8. The pattern forming method of claim 1,
wherein the step of etching the second spacer film is performed by using RIE (Reactive Ion Etching).

9. The pattern forming method of claim 1,
wherein the step of forming the second spacer pattern is performed by performing a treatment on the substrate with a HF (Hydrogen Fluoride) solution.

10-17. (canceled)
